(19) United States
(12) Patent Application Publication
(10) Pub. No.: US 2007/0029541 A1
(43) Pub. Date: Feb. 8, 2007

(54) High efficiency light emitting device

(76) Inventors: Huoping Xin, Brea, CA (US); Xingquan Liu, Brea, CA (US); Xiaohong Shi, Brea, CA (US); Chan Kyung Choi, Brea, CA (US); Jin Soo Song, Brea, CA (US)

Correspondence Address: Gregory B. Gulliver;THE ECLIPSE GROUP, 10453 Raintree Lane, Northridge, CA, 91326, US

(21) Appl. No.: 11/196,856

(22) Filed: Aug. 4, 2005

(51) Int. Cl. H01L 31/109

(52) U.S. Cl. 257/14

(57) ABSTRACT

A highly efficient III-nitride/II-Oxide light emitting device that has a n⁺⁺-tunneling layer, which comprises at least one material selected from a group consisting of n⁺⁺-GaN, n⁺⁺-InGaN, n⁺⁺-AlGaN, n⁺⁺-AlGaInN, n⁺⁺-ZnO, n⁺⁺-ZnCdO, n⁺⁺-ZnMgO, n⁺⁺-ZnMgCdO, that is deposited on top of the p-layer in a LED structure. After that, a top n-layer is deposited above that n⁺⁺-tunneling layer that may be a n⁺-layer and comprises at least one material selected from a group consisting of n⁺-GaN, n⁺-InGaN, n⁺-AlGaN, n⁺-AlGaInN, n⁺-ZnO, n⁺-ZnCdO, n⁺-ZnMgO, n⁺-ZnMgCdO or a top n-layer may also be a n⁺⁺-layer and comprises at least one material selected from a group consisting of n⁺⁺-GaN, n⁺⁺-InGaN, n⁺⁺-AlGaN, n⁺⁺-AlGaInN, n⁺⁺-ZnO, n⁺⁺-ZnCdO, n⁺⁺-ZnMgO, n⁺⁺-ZnMgCdO so that the top n-layer is made highly conductive and show very rough surface.

### BACKGROUND OF THE INVENTION

1. Field of the Invention

The invention relates to high efficiency light emitting devices, and more particularly to III-nitride/II-Oxide light emitting devices.

2. Related Art

There is a growing demand worldwide for solid state visible and ultraviolet (UV) light emitting diodes (LEDs) due to their huge, expanding market for applications such as traffic lights, full color displays, LCD back-lighting, automobile, stage, and museum lighting, and general illumination. Typically, most commercial solid state LEDs are III-nitride based LEDs, which use Mg-doped III-nitride layers as the top p-type contact material. However, the difficulty in ionizing Mg dopants inevitably results in a highly resistive p-Ga(Al, In)N layer, large metal/p-Ga(Al, In)N contact resistance, and poor current spreading. These drawbacks limit the performance of the III-nitride-based LEDs. Therefore, what is needed in the art is an approach that reduces the contact resistance between the p-metal and p-Ga(Al, In)N layer, and increases current spreading in the p-Ga(Al, In)N layer.

In addition, the optical transmittance of the p-metal layer is an important issue to be taken into account since photons generated in the active region tend to be partially absorbed by this layer. Increasing the doping level of Mg for higher conductivity is not effective, and would increase the light absorption substantially. Therefore, it is also desirable to have an approach that overcomes these difficulties in p-contact region.

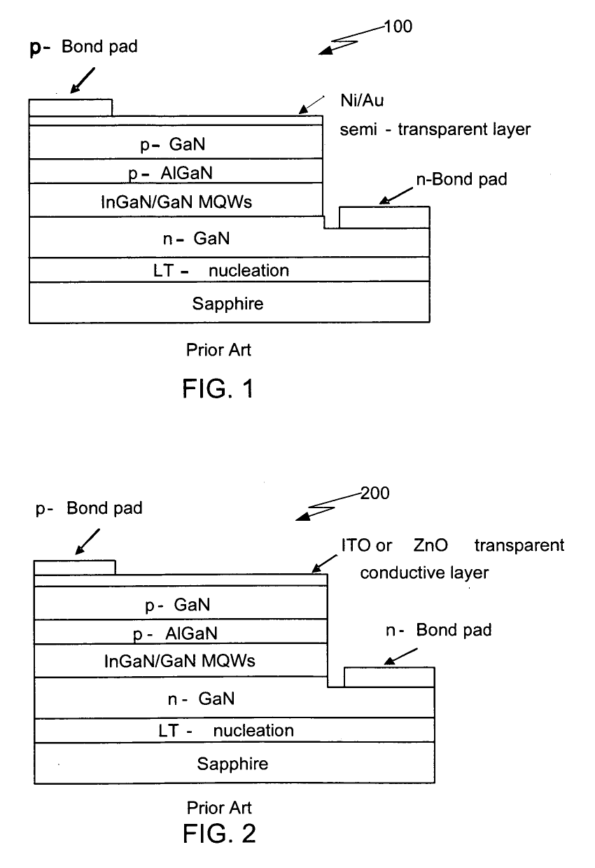

Conventional nitride-based LEDs 100, as shown in FIG. 1 use semitransparent Ni—Au deposited on Mg-doped p-Ga(Al, In)N layer as the p-contact material to reduce the contact resistance and enhance the current spreading. However, Ni—Au layer partially absorbs photons generated in the active region, which lowers the LED light output. The transmittance of Ni—Au layer is related to its thickness, and the typical value is only 60-75% as described by C. L. Tseng, M. J. Youh, G. P. Moore, M. A. Hopkins, R. Stevens, and W. N. Wang, in Appl. Phys. Lett. 83, 3677 (2003) and by S. P. Jung, C. H. Lin, H. M. Chan, Z. Y. Fan, J. G. Lu, and H. P. Lee, in Phys. Stat. Sol (a) 201, 2887 (2004).

To achieve highly efficient LEDs, it is desirable to reduce the contact resistance and enhance the transmission efficiency at the p-contact layers simultaneously. In a prior-art approach, an n⁺-InGaN/GaN short-period-superlattice (SPS) tunneling contact layer was deposited on top of the p-Ga(Al, In)N layer as described by S. J. Chang, C. S. Chang, Y. K. Su, R. W. Chuang, W. C. Lai, C. H. Kuo, Y. P. Hsu, Y. C. Lin, S. C. Shei, H. M. Lo, J. C. Ke, and J. K. Sheu, in IEEE Photon. Technol. Lett. 16, 1002 (2004). It was found that a good ohmic contact was achieved at the n⁺-InGaN/GaN and p-Ga(Al, In)N junction that is reverse-biased. A transparent indium-tin-oxide (ITO) layer was further used as the p-contact material instead of semitransparent Ni—Au layer. By adopting this method, the LED output intensity was increased by approximately 30% compared with the conventional Ni—Au on p-Ga(Al, In)N LED structures.

This prior art LED 200 shown in FIG. 2, however, requires post-deposition of the ITO layer after epitaxial growth of the LED structure, and more complicated processing procedure to roughen the ITO layer for light extraction enhancement as described by K. M. Chang, J. Y. Chu, C. C. Cheng, and C. F. Chu, in Phys. Stat. Sol.(c) 2, 2920 (2005) in which an increase in process complexity and manufacturing costs results.

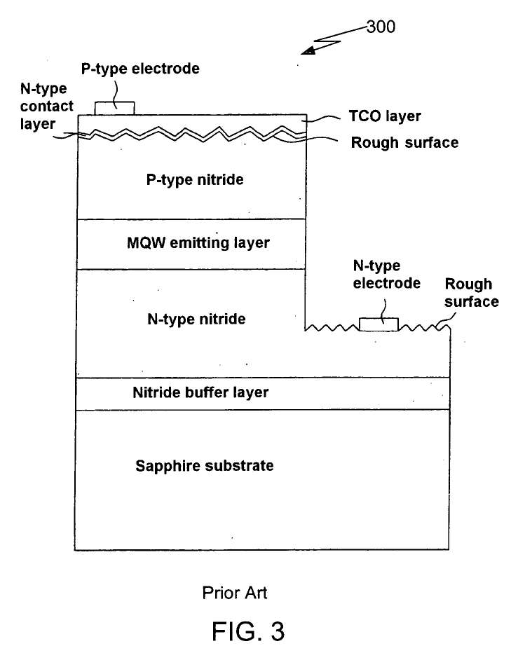

In prior art LED 300 shown in FIG. 3, a rough surface is formed over the p-Ga(Al, In)N layer to improve light extraction as described in US Patent Application Publication number 2005/0082562, which is incorporated by reference herein. Then a thin n-type reverse tunneling contact layer is grown at the top of the roughed p-GaN layer. However, an additional Transparent Conductive Oxide (TCO) layer is required above the rough surface for current spreading. This TCO layer introduces an extra interface that reflects lights back into the nitride layers and in turn lowers the efficiency of light extraction. The deposition of this TCO layer has to use a system different from nitride growth and therefore increases the overall processing complexity.

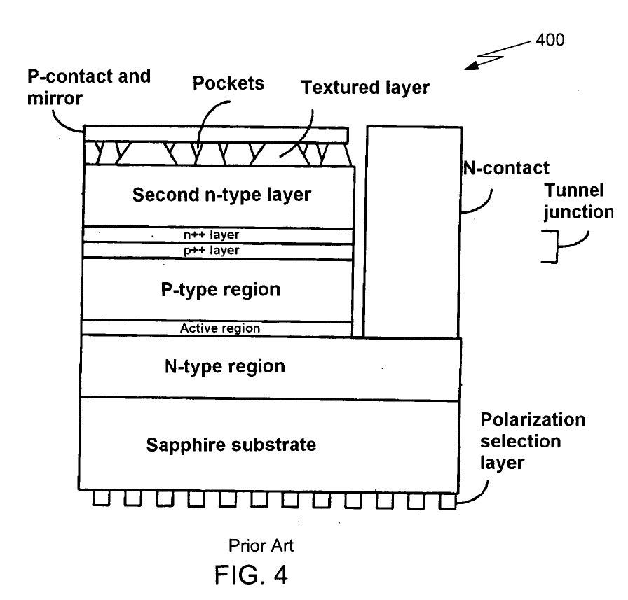

In prior art LED 400 shown in FIG. 4, a textured n-type layer is fabricated on top of tunnel junction layers as described in US Patent Application Publication number 2005/0023549, which is incorporated by reference herein. After that, a smooth metal mirror is deposited above the textured n-type layer. With its voids filled with low-index material, this textured layer serves as a polarization randomizer to change the polarization of lights generated at the active region and reflected by the metal mirror at the very top of the device. In this way, polarized lights extracted from the substrate surface at the bottom are claimed to be more efficient. Lights reflected by the top mirror have to travel through the active region and have a high probability of being re-absorbed. Therefore the device efficiency is limited. In addition, void filling and mirror coating require complicated post-deposition processes, which would lower the device reliability and increase the fabrication costs.

Therefore, there is a need in the art for an LED and method to produce LED devices that will overcome the drawbacks and issues in the known approaches discussed above.

### SUMMARY

The present invention relates to III-nitride/II-Oxide optoelectronic devices, and methods of making highly efficient light emitting devices, more particularly to improve performance of III-nitride/II-Oxide light emitting devices.

In the current approach, as an example, an n⁺⁺-layer, which can be grown directly on top of the p-Ga(Al, In)N layer in normal LED structures using the MOCVD or similar epitaxial growth technique, is adopted to form a tunneling junction with the p-Ga(Al, In)N layer. The n⁺⁺-layer can be made of GaN, InGaN, AlGaN, AlInGaN, or short period superlattice (SPS) layers consisting of any two of these materials, such as InGaN/GaN SPS. After that, a layer of n⁺-GaN can be grown or attached on top of the tunneling layer. By optimizing the growth conditions with higher doping concentration, the top n⁺-layer can be made highly conductive and show very rough surface. Therefore, it can serve dual functions. One is to act as a current spreading layer to improve the hole injection uniformity and efficiency. Another function is to increase light extraction due to the rough surface.

The top n⁺-GaN layer has an absorption band at shorter wavelengths than for the p-Ga(Al, In)N, and does not absorb the photons generated by the active layer(s). Its surface is chemically pure and does not contain extra defects that absorb lights. The rough surface on the other hand promotes light extraction to the external media through processes of either refraction or scattering, thus increases the LED light extraction efficiency.

The top n⁺-layer is highly conductive and does not require a TCO current spreading layer on top as in prior art LEDs. Further, the simplified structure eliminates the interface between the TCO and the ambient (air or device encapsulant), which traps a portion of the light within the device and lowers the overall efficiency.

The dual functionality of the top n⁺-GaN layer also simplifies the wafer processing procedures, since this approach does not require post-deposition of ITO or other transparent current spreading layer on the MOCVD-grown LED wafers. Cost reduction and yield improvement in device manufacturing thus may be achieved. The whole structure may be continuously grown by MOCVD, HVPE, MBE, sputtering, pulsed laser deposition, chemical vapor deposition, physical vapor deposition, etc., or any combination of these techniques as well.

Other systems, methods, features and advantages of the invention will be or will become apparent to one with skill in the art upon examination of the following figures and detailed description. It is intended that all such additional systems, methods, features and advantages be included within this description, be within the scope of the invention, and be protected by the accompanying claims. BRIEF DESCRIPTION OF THE FIGURES

The components in the figures are not necessarily to scale, emphasis instead being placed upon illustrating the principles of the invention. In the figures, like reference numerals designate corresponding parts throughout the different views.

FIG. 1 shows a schematic device structure of conventional InGaN/GaN LEDs with p-Ga(Al, In)N as the top contact layer.

FIG. 2 shows a prior art sectional view of a light-emitting diode with ITO or ZnO on top of the p-Ga(Al, In)N layer.

FIG. 3 shows a prior art sectional view of a rough surface formed over the p-Ga(Al, In)N layer to improve light extraction.

FIG. 4 shows a prior art sectional view of a textured n-type layer fabricated on top of tunnel junction layers.

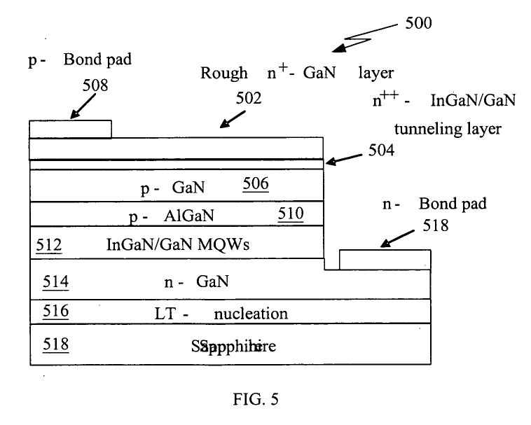

FIG. 5 show an example of schematic device structure with a rough n⁺-GaN layer on top of the n⁺⁺-tunneling layer above p-Ga(Al, In)N in the current implementation of a InGaN/GaN LED.

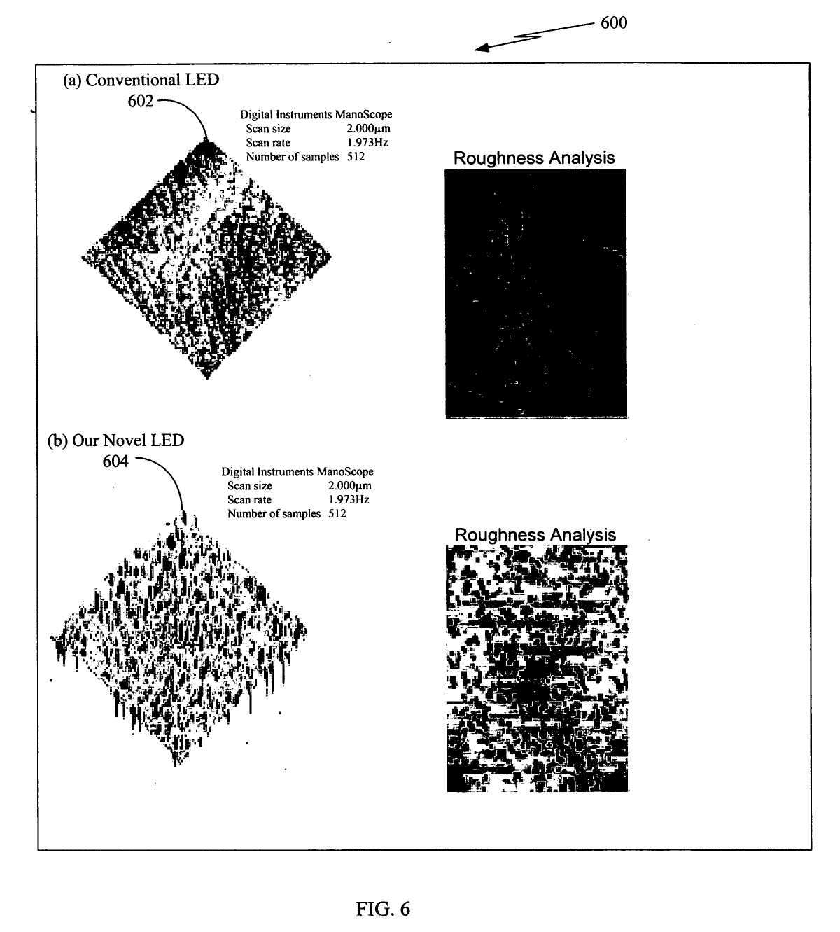

FIG. 6 shows AFM images of wafer surface of (a) conventional LED, (b) high efficiency LED.

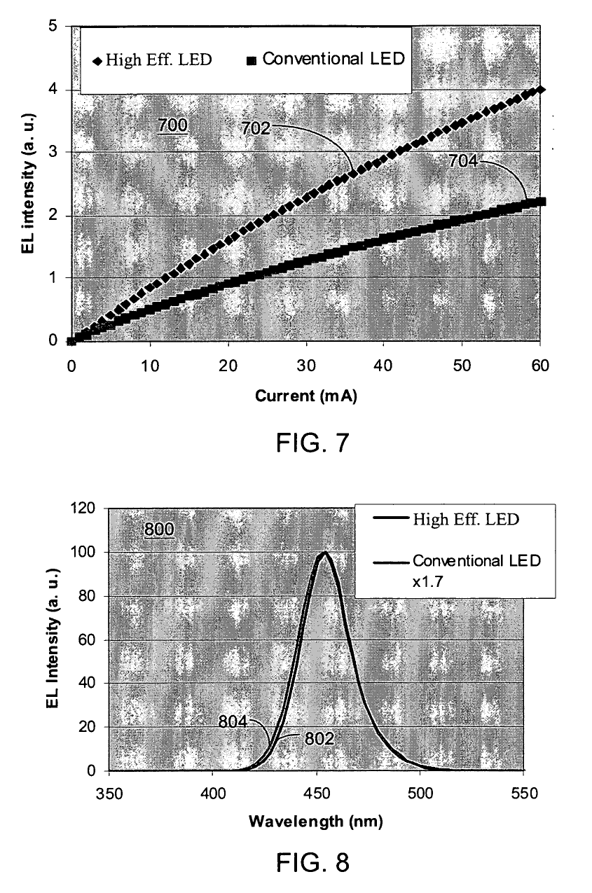

FIG. 7 shows L-I curves of both conventional and high efficiency LEDs.

FIG. 8 shows EL spectra of both conventional and high efficiency LEDs.

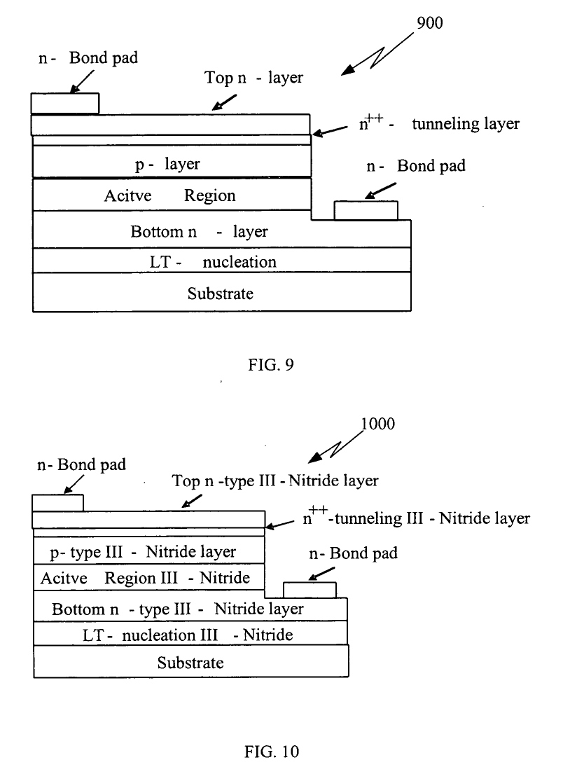

FIG. 9 shows the structure of a high efficiency LED.

FIG. 10 an implementation of the high efficiency LED based on III-Nitride materials.

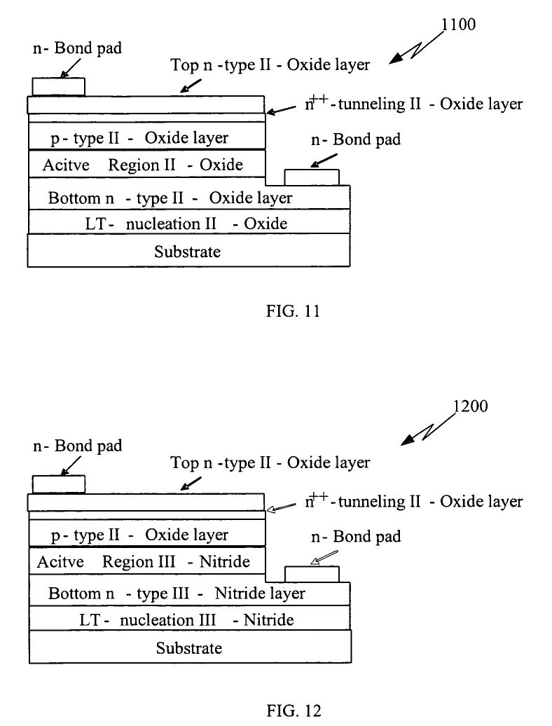

FIG. 11 shows a second implementation of the high efficiency LED based on II-Oxide materials.

FIG. 12 shows a third implementation of the high efficiency LED based on III-Nitride/II-Oxide hybrid structures.

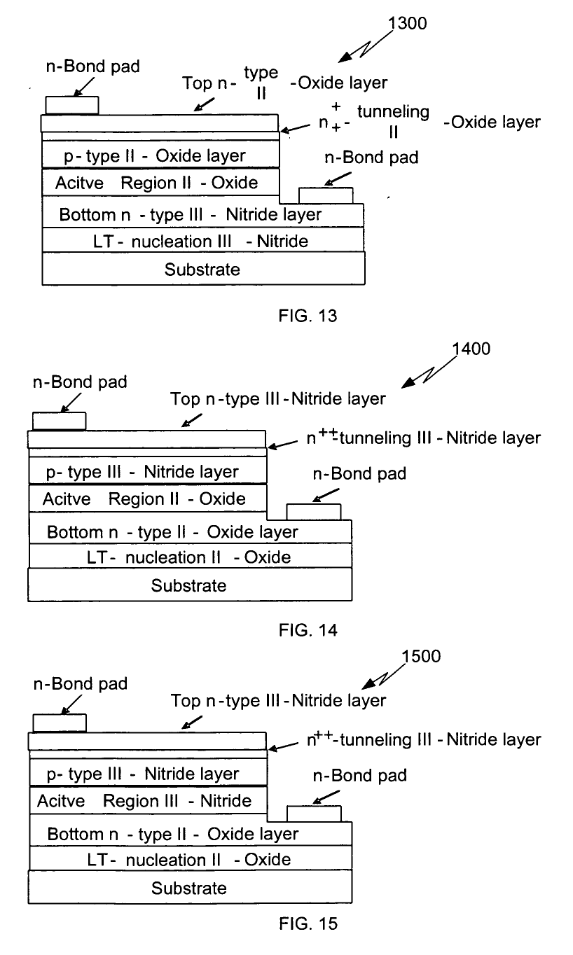

FIG. 13 shows a fourth implementation of the high efficiency LED based on III-Nitride/II-Oxide hybrid structures.

FIG. 14 shows a fifth implementation of the high efficiency LED based on II-Oxide/III-Nitride hybrid structures.

FIG. 15 shows a sixth implementation of the high efficiency LED based on II-Oxide/III-Nitride hybrid structures.

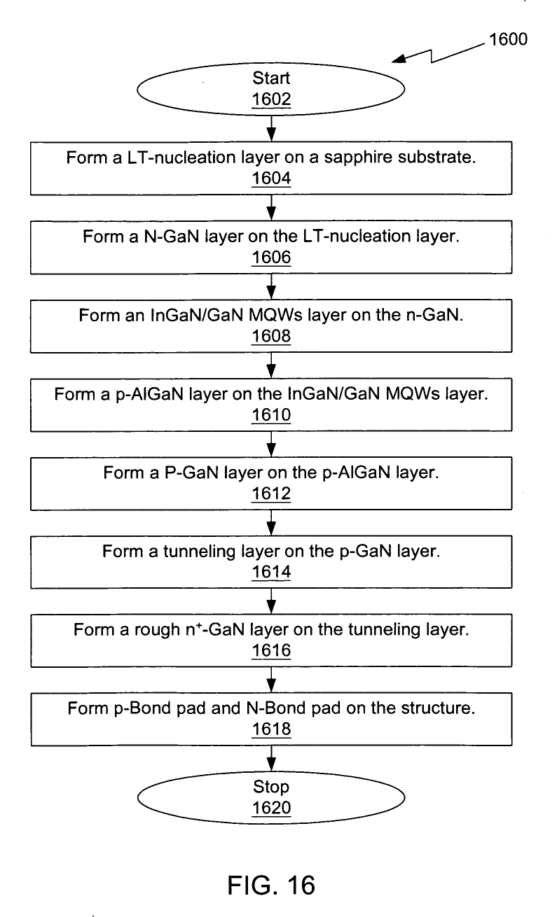

FIG. 16 shows a flow diagram of the process of forming the different layers of the high efficiency III-Nitride.

### DETAILED DESCRIPTION

In the following description of the preferred implementation, reference is made to the accompanying drawings that form a part hereof, and in which is shown by way of illustration a specific implementation in which the invention may be practiced. It is to be understood that other implementations may be utilized and structural changes may be made without departing from the scope of the present invention.

The present implementation reveals a high efficiency III-Nitride LED. Compared with the conventional LED, an additional n⁺-GaN layer and an n⁺⁺-tunneling layer directly grown on top of the p-Ga(Al, In)N surface are utilized to improve both current spreading and light extraction of a high efficiency III-Nitride LED. This high efficiency III-Nitride LED has demonstrated significant improvement in light output, 70% more than conventional LEDs, or 30% more than the prior-art LEDs. The manufacture of the high efficiency III-Nitride LED is by a simplified process as compared to the manufacture of prior-art LEDs while reducing manufacturing costs.

In FIG. 5, a schematic device structure 500 of a InGaN/GaN LED with a rough n⁺-Nitride layer 502 on top of the n⁺⁺-tunneling layer 504 above p-Ga(Al, In)N layer 506 is shown. A p-Bond pad 508 is formed on the rough n⁺-Nitride layer 502. The p-Ga(Al, In)N layer 506 may be formed on a p-AlGaN layer 510. The p-AlGaN layer 510 is formed on a InGaN/GaN multiple-quantum-wells (MQWs) layer 512, that may be formed on a n-GaN layer 514. The n-GaN layer 514 may be formed on an LT-nucleation layer 516. The LT-nucleation layer 516 may be formed on a sapphire substrate 518. An n-Bond pad 518 may be formed on the n-GaN layer 514.

Unlike the prior art LEDs of FIGS. 1 and 2, the n⁺⁺-layer 504 of the current implementation may be made of GaN, InGaN, AlGaN, AlInGaN, or SPS layers consisting of any two of these materials. A layer of n⁺⁺-Nitride and/or n⁺-Nitride layer may be grown subsequently on top of the tunneling layer. By increasing the doping concentration and optimizing the growth conditions, the top n⁺⁺- or n⁺-layer may become highly conductive and show very rough surface.

In FIG. 6, images 600 depicting the surface roughness of a conventional LED 602 and the high efficiency III-Nitride LED 604 are shown. The surface roughness of the high efficiency III-Nitride LED 604 has a root-mean-square (RMS) value of 1.75 nm, much larger than 0.25 nm for a conventional LED. The high efficiency III-Nitride LED surface 604 also shows lots of circular indents, which are very helpful in light extraction processes. Therefore, the top n⁺⁺- and/or n⁺-GaN layer improves the LED performance in two aspects: its high conductivity lowers the contact resistance and increases current spreading, thus improving the hole injection efficiency; whereas its rough surface allows more lights to escape from the device and directly increases the LED efficiency.

Turning to FIG. 7, a graph 700 of L-I curves of the high efficiency III-Nitride LED 702 and the convention LED 704 are shown. It is depicted in the graph 700 that an over 70% improvement in light output may be achieved by the high efficiency III-Nitride LED structure instead of the conventional LED.

The EL spectra of the high efficiency III-Nitride LED and the conventional LED chip are shown in the graph 800 of FIG. 8. The spectral profiles 802 and 804 are nearly the same, indicating no fundamental changes in device properties. Moreover, the intensity of the high efficiency III-Nitride LED is 70% higher than that of the conventional LED, showing the improvement in efficiency.

In further measurements, both the high efficiency III-Nitride LED and the conventional LED chips are packaged into lamps with resin encapsulant. At 20 mA current injection, the total output power was measured to be 10.7 mW for the high efficiency III-Nitride LEDs and 6.7 mW for the conventional LEDs. This shows a 60% increase in LED lamp output power, nearly consistent with the results measured on wafers depicted in FIGS. 7 and 8.

In FIG. 9, a diagram of another high efficiency III-Nitride LED structure 900 is shown. The high efficiency light emitting device may have a substrate; a low-temperature nucleation layer; a bottom n-type semiconductor layer; an unintentionally doped active layer or quantum well active layers; a p-type semiconductor layer; an n⁺⁺-tunneling layer on top of the p-layer; a top n-layer on top of the n⁺⁺-tunneling layer; an electrode formed on each of said top n-layer and the mesa-etched bottom n-type semiconductor layer.

The substrate of the high efficiency light emitting device may be made from one or more of the following material; SiC, Si, ZnO, MgO, Zn_{1-x-y}MgₓCd_{y}O, (where x=0˜1, y=0˜1), ZnSO, LiAlO₂, LiGaO₂, MgAl₂O₄, ScAlMgO₄, A1₂O₃(sapphire), AlN, GaN, InN, Al_{1-x-y}InₓGa_{y}N, (where x=0˜1, y=0˜1), InP, GaAs, and glass. Alternate implementations of the high efficiency LED structure 1000, 1100, 1200, 1300, 1400 and 1500 are shown in FIGS. 10, 11, 12, 13, 14 and 15, respectively. The bottom n-type semiconductor layer of the high efficiency light emitting device may be any n-type III-nitride layer including n-GaN, n-InGaN, n-AlGaN, and n-AlGaInN, or any n-type II-oxide layer including n-ZnO, n-ZnMgO, n-ZnCdO and n-ZnMgCdO.

The active region of the high efficiency LED may be selected from a group consisting of III-Nitride materials, such as GaN, InGaN, AlGaN, AlGaInN, or II-Oxides such as ZnO, ZnMgO, ZnCdO and ZnMgCdO.

The p-layer may have at least one III-Nitride materials, such as p-GaN, p-InGaN, p-AlGaN, p-AlGaInN, or II-Oxides such as p-ZnO, p-ZnMgO, p-ZnCdO and p-ZnMgCdO.

The high efficiency LED has an n⁺⁺-tunneling layer. The n⁺⁺-tunneling layer is composed of at least one of the following; n⁺⁺-GaN, n⁺⁺-InGaN, n⁺⁺-AlGaN, n⁺⁺-AlGaInN, n⁺⁺-ZnO, n⁺⁺-ZnCdO, n⁺⁺-ZnMgO, n⁺⁺-ZnMgCdO. The n⁺⁺-tunneling layer may also be an n⁺⁺-SPS layer with any two of these nitride or oxide compounds. The n⁺⁺-layer should be super conductive with electron concentration in the range of 1e19 to 5e20 cm⁻³. The n⁺⁺-layer thickness may be in the range of 0.5 to 100 nm.

The top n-layer of the high efficiency LED may be n⁺-layer. The n-layer may be composed of at least one of n⁺-GaN, n⁺-InGaN, n⁺-AlGaN, n⁺-AlGaInN, n⁺-ZnO, n⁺-ZnCdO, n⁺-ZnMgO, n⁺-ZnMgCdO. The top n-layer should be highly conductive with electron concentration in the range of 2e18 to 1e20 cm⁻³. The top n-layer thickness may be in the range of 5 to 2000 nm. In alternate implementations, the top n-layer may be an n⁺⁺-layer. The n⁺⁺-layer may have at least one material such as; n⁺⁺-GaN, n⁺⁺-InGaN, n⁺⁺-AlGaN, n⁺⁺-AlGaInN, n⁺⁺-ZnO, n⁺⁺-ZnCdO, n⁺⁺-ZnMgO, n⁺⁺-ZnMgCdO. The top n⁺⁺-layer should be highly conductive with electron concentration in the range of 1e19 to 5e20 cm⁻³. The top n⁺⁺-layer thickness may be in the range of 5 to 2000 nm. Furthermore, the top n-layer may also have a roughness of 0.01˜1 nm, and is exposed to the ambient with 1˜100% of its surface. The top n-layer achieves the surface roughness by its native semiconductor layer growth. In other implementations either dry etching or wet etching after the semiconductor layer growth may create the surface roughness.

The high efficiency LED may have all semiconductor layers grown by a single method, such as; Metal-Organic Vapor Phase Epitaxy (MOCVD), Hydride Vapor Phase Epitaxy (HVPE), Molecular beam Epitaxy (MBE), sputtering, pulsed laser deposition, chemical vapor deposition, or physical vapor deposition. In other implementations, the high efficiency LED may use more than one semiconductor growth method, such as semiconductor layers grown by a combination of two or more of the following approaches for forming semiconductor layers; Metal-Organic Vapor Phase Epitaxy (MOCVD), Hydride Vapor Phase Epitaxy (HVPE), Molecular beam Epitaxy (MBE), sputtering, pulsed laser deposition, chemical vapor deposition, and physical vapor deposition. The high efficiency may have an electrode contact made of metal. Examples of types of metal that are acceptable include Au, Pt, Al, Ti, Co, Pd, Cu, Ta, and Ni.

Turning to FIG. 16, a flow diagram of the process of forming the different layers of the high efficiency LED is shown. The process starts 1602 with a sapphire substrate 518 upon which an LT-nucleation layer 516 is formed 1604. An n-GaN layer 514 is then formed on the LT-nucleation layer 516 in step 1606. An InGaN/GaN MQWs layer 512 may be formed on the N-GaN layer 514 in step 1608. In step 1610, a P-AlGaN layer 510 may be formed on the InGaN/GaN MQWs layer 512. A P-GaN layer 506 is then formed on the P-AlGaN layer 510, in step 1612. In step 1614, the tunneling layer 504 is formed on the p-GaN layer 506. On top of the tunneling layer 504, a rough N⁺-GaN layer 502 may be formed in step 1616. Bond pads are then formed on the structure 1618, thus completing formation of the high efficiency LED 1620. A p-Bond pad 508 is formed on the rough N⁺-GaN layer 502 and an n-Bond pad 518 may be formed on the n-GaN layer 514. The different layers may be created by using one or more of the following approaches: Metal-Organic Vapor Phase Epitaxy (MOCVD), Hydride Vapor Phase Epitaxy (HVPE), Molecular beam Epitaxy (MBE), sputtering, pulsed laser deposition, chemical vapor deposition, or physical vapor deposition.

The high efficiency LED fabrication technology may be used in numerous applications, including light emitting diodes (LEDs), semiconductor lasers, optical modulators and amplifiers, and other devices employing light emitting processes including but not limited to spontaneous emission, stimulated emission, and super-luminescence. Further, the high efficiency LED may emit light in UV or visible spectrum, including ultraviolet, violet, blue, green, yellow, orange, and red.

The foregoing description of an implementation has been presented for purposes of illustration and description. It is not exhaustive and does not limit the claimed inventions to the precise form disclosed. Modifications and variations are possible in light of the above description or may be acquired from practicing the invention.

What is claimed is:

1. A high efficiency LED structure, comprising:
a substrate;
a low-temperature nucleation layer that is on top of the substrate;
a bottom n-type semiconductor layer on top of the low-temperature nucleation layer;
an active layer on top of the n-type semiconductor layer;
a p-type semiconductor layer on top of the active layer;
an n⁺⁺-tunneling layer on top of the p-type semiconductor layer;
a top n-layer on top of the n⁺⁺-tunneling layer; and
an electrode contact coupled to the top n-layer and another electrode contact coupled to the bottom n-type semiconductor layer.

2. The high efficiency LED structure of claim 1, wherein substrate is made up of at least one material selected from a group consisting of SiC, Si, ZnO, MgO, Zn_{1-x-y}MgₓCd_{y}O, (where x=0˜1, y=0˜1), ZnSO, LiAlO₂, LiGaO₂, MgAl₂O₄, ScAlMgO₄, Al₂O₃(sapphire), AlN, GaN, InN, Al_{1-x-y}InₓGa_{y}N, (where x=0˜1, y=0˜1), InP, GaAs, and glass.

3. The high efficiency LED structure of claim 1, wherein the bottom n-type semiconductor layer is an n-type III-nitride layer.

4. The high efficiency LED structure of claim 3, where the n-type III-nitride is selected from a group consisting of n-GaN, n-InGaN, n-AlGaN, and n-AlGaInN.

5. The high efficiency LED structure of claim 3, where the n-type III-nitride is a n-type II-oxide layer.

6. The high efficiency LED structure of claim 1, wherein the active region is made up of at least one material selected from a group consisting of GaN, InGaN, AlGaN, AlGaInN, ZnO, ZnMgO, ZnCdO and ZnMgCdO.

7. The high efficiency LED structure of claim 1, wherein the p-layer is made of at least one material selected from a group consisting of p-GaN, p-InGaN, p-AlGaN, p-AlGaInN, p-ZnO, p-ZnMgO, p-ZnCdO and p-ZnMgCdO.

8. The high efficiency LED structure of claim 1, wherein the ne-tunneling layer is made of at least one material selected from a group consisting of n⁺⁺-GaN, n⁺⁺-InGaN, n⁺-AlGaN, n⁺-AlGaInN, n⁺⁺-ZnO, n⁺⁺-ZnCdO, n⁺⁺-ZnMgO, n⁺⁺-ZnMgCdO.

9. The high efficiency LED structure of claim 1, wherein the n⁺⁺-tunneling layer is made of an n⁺⁺-SPS layer made up of any two nitride or oxide compounds such that the n⁺⁺-tunneling layer is super conductive with electron concentration in the range of 1e19 to 5e20 cm⁻³.

10. The high efficiency LED structure of claim 9, where the n⁺⁺-tunneling layer has a thickness in the range of 0.5 to 100 nm.

11. The high efficiency LED structure of claim 1, wherein the top n-layer made up of at least one material selected from a group consisting of n⁺-GaN, n⁺-InGaN, n⁺-AlGaN, n⁺-AlGaInN, n⁺-ZnO, n⁺-ZnCdO, n⁺-ZnMgO, and n⁺-ZnMgCdO.

12. The high efficiency LED structure of claim 11, where the top n-layer has an electron concentration in the range of 2e18 to 1e20 cm⁻³ electrons.

13. The high efficiency LED structure of claim 11, where the top n-layer thickness is in the range of 5 to 2000 nm.

14. The high efficiency LED structure of claim 1, wherein the top n-layer is made from at least one material selected from a group consisting of n⁺⁺-GaN, n⁺⁺-InGaN, n⁺⁺-AlGaN, n⁺⁺-AlGaInN, n⁺⁺-ZnO, n⁺⁺-ZnCdO, n⁺⁺-ZnMgO, and n⁺⁺-ZnMgCdO.

15. The high efficiency LED structure of claim 14, where the top n-layer has an electron concentration in the range of 1e19 to 5e20 cm⁻³.

16. The high efficiency LED structure of claim 14, where the top n-layer thickness is in the range of 5 to 2000 nm.

17. The high efficiency LED structure of claim 1, wherein said top n-layer has a roughness of 0.01˜1 nm, and is exposed to the ambient with 1˜100% of its surface.

18. The high efficiency LED structure of claim 1, wherein all layers are grown by at least one growth approach selected from the group growth approaches consisting of Metal-Organic Vapor Phase Epitaxy (MOCVD), Hydride Vapor Phase Epitaxy (HVPE), Molecular beam Epitaxy (MBE), sputtering, pulsed laser deposition, chemical vapor deposition, and physical vapor deposition.

19. The high efficiency LED structure of claim 1, wherein the electrode contact and the other electrode contact are made from metals that are selected from a group of materials consisting of Au, Pt, Al, Ti, Co, Pd, Cu, Ta, and Ni.

20. A method for a high efficiency LED structure, comprising:
forming a low-temperature nucleation layer on top of a substrate;
forming a bottom n-type semiconductor layer on top of the low-temperature nucleation layer;
forming an active layer on top of the n-type semiconductor layer;
forming a p-type semiconductor layer on top of the active layer;
forming an n⁺⁺-tunneling layer on top of the p-type semiconductor layer;
forming a top n-layer on top of the n⁺⁺-tunneling layer; and
creating an electrode contact coupled to the top n-layer and another electrode contact coupled to the bottom n-type semiconductor layer.

21. The method for a high efficiency LED structure of claim 20, wherein substrate is made up of at least one material selected from a group consisting of SiC, Si, ZnO, MgO, Zn_{1-x-y}MgₓCd_{y}O (where x=0˜1, y=0˜1), ZnSO, LiAlO₂, LiGaO₂, MgAl₂O₄, ScAlMgO₄, A1₂O₃(sapphire), AlN, GaN, InN, Al_{1-x-y}InₓGa_{y}N, (where x=0˜1, y=0˜1), InP, GaAs, and glass.

22. The method for a high efficiency LED structure of claim 20, wherein the bottom n-type semiconductor layer is an n-type III-nitride layer.

23. The method for a high efficiency LED structure of claim 22, where the n-type III-nitride is selected from a group consisting of n-GaN, n-InGaN, n-AlGaN, and n-AlGaInN.

24. The method for a high efficiency LED structure of claim 22, where the n-type III-nitride is a n-type II-oxide layer.

25. The method for a high efficiency LED structure of claim 20, wherein the active region is made up of at least one material selected from a group consisting of GaN, InGaN, AlGaN, AlGaInN, ZnO, ZnMgO, ZnCdO and ZnMgCdO.

26. The method for a high efficiency LED structure of claim 20, wherein the p-layer is made of at least one material selected from a group consisting of p-GaN, p-InGaN, p-AlGaN, p-AlGaInN, p-ZnO, p-ZnMgO, p-ZnCdO and p-ZnMgCdO.

27. The method for a high efficiency LED structure of claim 20, wherein the n⁺⁺-tunneling layer is made of at least one material selected from a group consisting of n⁺⁺-GaN, n⁺⁺-InGaN, n⁺⁺-AlGaN, n⁺⁺-AlGaInN,.n⁺⁺-ZnO, n⁺⁺-ZnCdO, n⁺⁺-ZnMgO, n⁺⁺-ZnMgCdO.

28. The method for a high efficiency LED structure of claim 20, wherein the n⁺⁺-tunneling layer is made of an n⁺⁺-SPS layer made up of any two nitride or oxide compounds such that the n⁺⁺-tunneling layer is super conductive with electron concentration in the range of 1e19 to 5e20 cm³.

29. The method for a high efficiency LED structure of claim 28, where the n⁺⁺-tunneling layer has a thickness in the range of 0.5 to 100 nm.

30. The method for a high efficiency LED structure of claim 20, wherein the top n-layer made up of at least one material selected from a group consisting of n⁺-GaN, n⁺-InGaN, n⁺-AlGaN, n⁺-AlGaInN, n⁺-ZnO, n⁺-ZnCdO, n⁺-ZnMgO, and n⁺-ZnMgCdO.

31. The method for a high efficiency LED structure of claim 30, where the top n-layer has an electron concentration in the range of 2e18 to 1e20 cm⁻³ electrons.

32. The method for a high efficiency LED structure of claim 30, where the top n-layer thickness is in the range of 5 to 2000 nm.

33. The high efficiency LED structure of claim 20, wherein the top n-layer is made from at least one material selected from a group consisting of n⁺⁺-GaN, n⁺⁺-InGaN, n⁺⁺-AlGaN, n⁺⁺-AlGaInN, n⁺⁺-ZnO, n⁺⁺-ZnCdO, n⁺⁺-ZnMgO, and n⁺⁺-ZnMgCdO.

34. The high efficiency LED structure of claim 33, where the top n-layer has an electron concentration in the range of 1e19 to 5e20 cm⁻³.

35. The high efficiency LED structure of claim 33, where the top n-layer thickness is in the range of 5 to 2000 nm.

36. The high efficiency LED structure of claim 20, wherein said top n-layer has a roughness of 1˜1,000 nm, and is exposed to the ambient with 1˜100% of its surface.

37. The high efficiency LED structure of claim 20, wherein all layers are grown by at least one procedure selected from the group consisting of Metal-Organic Vapor Phase Epitaxy (MOCVD), Hydride Vapor Phase Epitaxy (HVPE), Molecular beam Epitaxy (MBE), sputtering, pulsed laser deposition, chemical vapor deposition, and physical vapor deposition.

38. The high efficiency LED structure of claim 20, wherein the electrode contact and the other electrode contact are made from metals that are selected from a group of materials consisting of Au, Pt, Al, Ti, Co, Pd, Cu, Ta, and Ni.
